(19) United States
(12) Patent Application Publication
(10) Pub. No.: US 2012/0222618 A1
(43) Pub. Date: Sep. 6, 2012

(54) DUAL PLASMA SOURCE, LAMP HEATED PLASMA CHAMBER

(75) Inventors: Christopher Olsen, Fremont, CA (US); Canfeng Lai, Fremont, CA (US); Sundar Ramamurthy, Fremont, CA (US); Johanes S. Swenberg, Los Gatos, CA (US); Wei Liu, San Jose, CA (US)

(73) Assignee: APPLIED MATERIALS, INC., Santa Clara, CA (US)

(21) Appl. No.: 13/193,453

(22) Filed: Jul. 28, 2011

Related U.S. Application Data
(60) Provisional application No. 61/448,102, filed on Mar. 1, 2011.

(51) Int. Cl. C23C 16/50; C23C 16/505; C23C 16/511

(52) U.S. Cl. 118/723 MP; 118/723 R; 118/723 MA; 118/723 I

(57) ABSTRACT

Methods and apparatus for processing semiconductor substrates are described. A processing chamber includes a substrate support with an in-situ plasma source, which may be an inductive, capacitive, microwave, or millimeter wave source, facing the substrate support and a radiant heat source, which may be a bank of thermal lamps, spaced apart from the substrate support. The support may be between the in-situ plasma source and the radiant heat source, and may rotate. A method or processing a substrate includes forming an oxide layer by exposing the substrate to a plasma generated in a process chamber, performing a plasma nitridation process on the substrate in the chamber, thermally treating the substrate using a radiant heat source disposed in the chamber while exposing the substrate to oxygen radicals formed outside the chamber, and forming an electrode by exposing the substrate to a plasma generated in the chamber.

### CROSS-REFERENCE TO RELATED APPLICATIONS

This application claims benefit of U.S. Provisional Patent Application Ser. No. 61/448,102 filed Mar. 1, 2011, which is herein incorporated by reference.

### FIELD

Embodiments described herein relate to semiconductor manufacturing processes and apparatus. More specifically, methods and apparatus for forming and treating material layers on semiconductor substrates are disclosed.

### BACKGROUND

The CMOS field-effect transistor is the functional core of most semiconductor devices. Over the past 50 years, Moore's Law has driven reduction in the size of MOSFETs and closer packing of MOSFETs on smaller chips. As size has been reduced, manufacturing challenges have mounted.

Typically, a MOSFET includes a gate structure disposed over a channel region. The gate structure controls flow of electricity through the channel region by changing the electronic properties of the channel region when a voltage is applied to the gate structure. The gate structure generally includes a gate electrode and a gate dielectric between the gate electrode and the channel region. When a voltage is applied to the gate electrode, an electric field is established in the gate dielectric and the channel region that changes the flow of charge carriers through the channel region.

The gate dielectric is typically formed from silicon nitride, silicon oxynitride, metal oxide, metal nitride, or metal silicate. The gate electrode is commonly silicon. Various processes, including plasma CVD, thermal treatment, DPN, RTP, remote plasma processes, and oxidation processes are commonly performed on a substrate to build a MOSFET gate structure. In one process, a layer of silicon oxide is formed on a substrate in a PECVD chamber. The substrate is moved to a DPN chamber for nitridation. The substrate is moved to an RTP chamber for re-oxidation. Then the substrate is moved to a second PECVD chamber for silicon deposition. The chambers are generally coupled to a transfer chamber that moves the substrates from process to process.

Production platforms such as that described above, and the processes they perform, are expensive and have limited throughput. Pathways for processing substrates must be changed among the various chambers to change processing order, with impacts on throughput. Apparatus and methods of processing substrates using multi-functional chambers would streamline production, increase throughput, and reduce the need for substrate handling.

Accordingly, there is a continuing need for efficient and cost-effecting methods and apparatus for forming gate structures on substrates.

### SUMMARY

A chamber for processing semiconductor substrates is described in one embodiment. The chamber includes a substrate support with an in-situ plasma source facing the substrate support and a radiant heat source spaced apart from the substrate support. The substrate support may be between the in-situ plasma source and the radiant heat source. The radiant heat source may be a bank of thermal lamps. The in-situ plasma source may be an inductive or capacitive plasma source, or a microwave or millimeter wave plasma source.

The chamber may include a remote plasma source connected to the chamber and disposed through a wall facing the substrate support or adjacent to the substrate support. The remote plasma source may be connected to a gas distributor disposed through the in-situ plasma source. A window may be disposed between the radiant heat source and the substrate support, and the substrate support may rotate.

In another embodiment, a chamber is described having a high ion density plasma source and a low ion density plasma source, both positioned to expose a substrate disposed on a substrate support to a plasma. A radiant heat source may be included in the chamber, and may be located with the substrate support between the plasma sources and the radiant heat source.

In another embodiment, a method of processing a substrate in a processing chamber is provided. The method includes forming an oxide layer on the substrate by exposing the substrate to a plasma generated in the chamber, performing a plasma nitridation process on the substrate in the chamber, thermally treating the substrate using a radiant heat source disposed in the chamber while exposing the substrate to oxygen radicals formed outside the chamber, and forming an electrode on the substrate by exposing the substrate to a plasma generated in the chamber. The above steps may be performed without removing the substrate from the chamber.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a processing chamber according to one embodiment.

FIG. 2 is a flow diagram summarizing a method according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

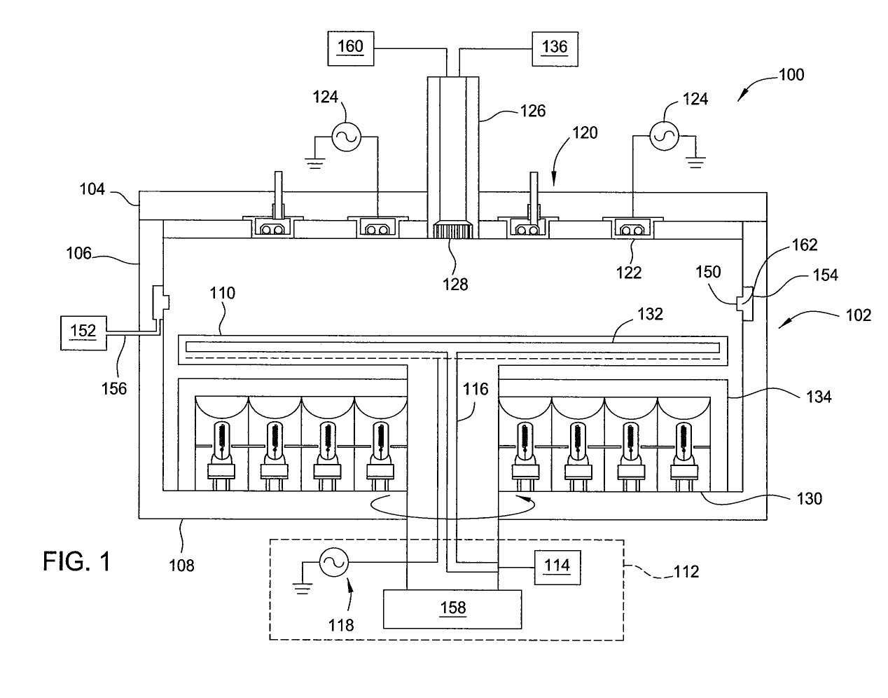

A multi-functional chamber may be configured to perform a variety of material and thermal processes on a substrate without removing the substrate from the chamber. FIG. 1 is a cross-sectional view of such a chamber 100 according to one embodiment. The chamber of FIG. 1 is capable of performing various plasma and thermal deposition and treatment processes on a substrate simultaneously, concurrently, or sequentially. The substrate may remain in the chamber while a series of processes is performed on the substrate, or the substrate may be removed at times and returned later to the chamber for subsequent processing.

The chamber 100 of FIG. 1 has an enclosure 102 with a first portion 104, a second portion 106, and a third portion 108. The enclosure 102 may be anodized aluminum or quartz, or may be anodized aluminum with a quartz chamber liner, such materials being resistant to most processes performed in manufacturing field-effect transistors. The first, second, and third portions 104, 106, and 108, may be formed integrally together or removably attached using fasteners (not shown).

A substrate support 110 is disposed within the enclosure 102, and extends through the third portion 108 to a control assembly 112. The control assembly 112 may have a motor rotationally coupled to the substrate support 110, a thermal control module 114 for providing a thermal control fluid through a conduit 116 in the substrate support, and an electrical unit 118 for providing electrical bias to the substrate support 110 or for electrostatically immobilizing a substrate on the substrate support 110.

A plasma source 120 is disposed in the first portion 104 of the enclosure 102 facing the substrate support 110. The plasma source 120 is an inductive plasma source comprising a plurality of conductive loops 122 energized by one or more RF power sources 124. A process gas source 160 is fluidly coupled to the chamber 100 by a process gas conduit 126 disposed through the plasma source 120, with a gas distributor 128 positioned in a central portion of the plasma source 120 facing the substrate support 110. Process gases to be activated by the plasma source 120 may be provided to the chamber 100 through the gas distributor 128. An inductive plasma source useful in the chamber 102 is described in commonly assigned U.S. patent application Ser. No. 12/780,531, entitled “Inductive Plasma Source With Metallic Shower Head Using B-Field Concentrator”, filed May 14, 2010, and incorporated herein by reference.

A heat source 130 is disposed in the enclosure 102, spaced apart from a surface 132 of the substrate support 110. The heat source 130 may be a radiant heat source, for example a plurality of heat lamps, which may be arranged in a bank, for example in a honeycomb pattern. A quartz window 134 is disposed between the heat source 130 and the substrate support 110 to control the radiation from the heat source 130, for example by allowing for filters to be applied to the quartz window to filter desired wavelengths and allow other wavelengths to propagate. The quartz window 134 may protect the heat source 130 from the process environment of the chamber 100. The substrate support 110 is shown positioned between the heat source 130 and the plasma source 120 for convenience, but such positioning is not required. For example, an annular heat source may be positioned around a periphery of the second part 106 of the enclosure 102 between the substrate support 110 and the plasma source 120, with a quartz window or shield separating the heat source from the process environment. In the embodiment of FIG. 1, the substrate support 110 may comprise a material that is substantially transparent to the radiation from the heat source 130, enabling thermal processing of a substrate disposed on the surface 132 of the substrate support 110.

A source of radicals 136 may be coupled to the chamber 100 through the process gas conduit 126 and gas distributor 128, or through alternative access points. The source of radicals 136 may be a remote plasma source, which may be energized by RF or microwave power.

Gases are exhausted from the chamber by coupling a pumping port 150 with a vacuum source 152. The pumping port 150 may be at any convenient location of the chamber. In the embodiment of FIG. 1, the pumping port 150 is a pumping plenum disposed in the second portion 106 of the enclosure 102 near the surface 132 of the substrate support 110. A substantially continuous opening 162 leads to a channel 154 that circumnavigates the chamber 100 and is connected to a vacuum conduit 156 leading to the vacuum source 152. The pumping port may also be a round portal formed in the enclosure 102 and coupled to the vacuum source 152 by a conduit.

The plasma source 120 of FIG. 1, as shown and described, is an inductive plasma source. In alternate embodiments, the plasma source 120 may be a capacitive plasma source such as a planar gas distributor disposed facing the substrate support 110 and generally parallel thereto. The planar gas distributor may have gas flow openings disposed through the surface of the gas distributor that faces the substrate support 110. The gas flow openings will generally communicate with one or more gas plenums formed in the gas distributor to ensure gas flows evenly through all the openings. Thermal control channels may be interspersed with the gas flow plenums to afford heating or cooling of the gas distributor and/or gases flowing through the gas distributor. Electrical power such as RF power is coupled to the planar gas distributor, the substrate support, or both to establish an electric field between the gas distributor and the substrate support.

In another embodiment, the plasma source 120 of FIG. 1 may be a microwave or millimeter wave source. A coaxial source of long-wave radiation may be disposed in a configuration facing the substrate support 110, with a reflector between the coaxial source and the first portion 104 of the enclosure 102 to direct the emitted radiation toward the substrate support 110. The coaxial source may be one or more coaxial cables arranged in an antenna structure that may be a spiral shape, a boustrophedonic shape, or any desired distributed shape. A magnetron power source is typically coupled to the coaxial antenna structure to establish the radiation field.

In the embodiment of FIG. 1, the substrate support 110 as shown and described is a pedestal-style substrate support. In an alternate embodiment, the substrate may be supported by an support ring extending inward from the second portion 106 of the enclosure between the heat source 130 and the plasma source 120. Such an arrangement may provide more direct access to the substrate for the heat source 130. In embodiments wherein the heat source 130 is a lamp array, a plurality of lift pins may be interspersed with the lamps and actuated by a lift pin assembly to engage the substrate and lift it above the support ring for transporation into and out of the chamber 100.

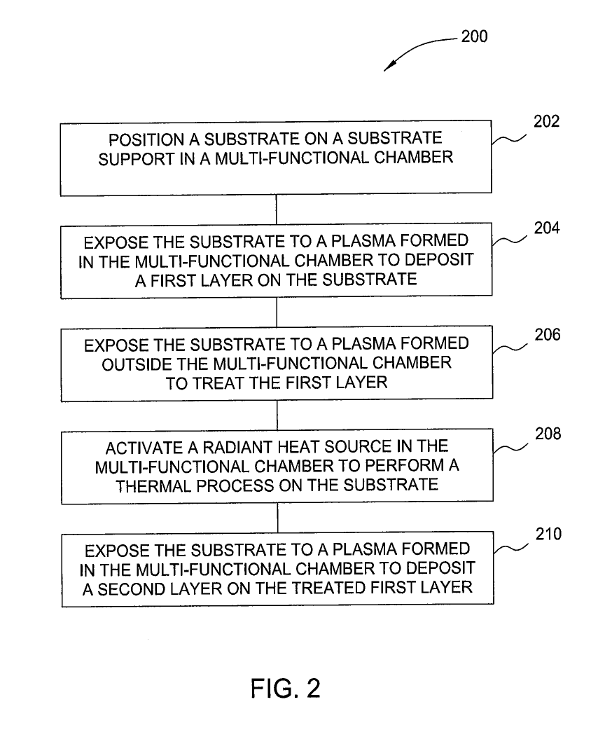

FIG. 2 is a flow diagram summarizing a method 200 according to another embodiment. At 202, a substrate is disposed on a substrate support in a multi-functional chamber, such as the chamber 100 of FIG. 1. At 204, the substrate is exposed to a plasma formed in the multi-functional chamber, and a layer is deposited on the substrate. A plasma source, which may be inductive or capacitive, disposed in the multi-functional chamber is energized with electric power, for example RF power at one or more frequencies between about 300 kHz and about 1,000 MHz, for example about 13.56 MHz. A deposition precursor gas is provided to a reaction space between the plasma source and the substrate support and activated by the plasma source. The activated precursor forms a layer on the substrate. In one embodiment, the deposition precursor is a silicon source such as silane, which forms a layer of silicon on the substrate. In another embodiment, the deposition precursor is a nitrogen source, such as nitrogen gas or ammonia, which may add nitrogen to the surface of the substrate, for example in a DPN process. In another embodiment, the deposition precursor may be a metal source or reducing gas for performing an ALD process. In general, the plasma formed in the chamber is an ion-rich plasma or a plasma having high ion density.

At 206, the substrate is exposed to a plasma formed outside the chamber, for example in a microwave or RF chamber remote from the chamber containing the substrate. The plasma is flowed into the chamber containing the substrate, and the substrate is exposed to the plasma. The plasma may be a remote plasma, but is generally a radical-rich plasma or a plasma having high radical density and/or low ion-density. Such a plasma may be provided to perform an oxidation process to repair an oxide layer that has been exposed to an ion-reactive process previously, such as the operation 204. Such a plasma may also be an nitrogen and fluorine containing plasma provided to perform a cleaning operation on the substrate. In some embodiments, a remote plasma may be provided to the chamber and re-activated by forming an electric field in the chamber, as in the operation 204 described above.

At 208, a radiant heat source disposed in the multi-functional chamber is activated to perform a thermal process on the substrate. The thermal process may be performed in the presence of a reactive gas, which may be activated by a plasma source disposed in the chamber, remote from the chamber, or both. In one example, a reoxidation process may be performed by activating the radiant heat source and heating the substrate to a temperature of at least about 600° C. while providing a gas comprising oxygen radicals. Such a reoxidation process may follow a process in which the substrate is exposed to a plasma formed in the chamber, such as the operation 204 described above. In one embodiment, a DPN operation and a subsequent reoxidation operation are performed on a substrate in a single multi-functional chamber such as the chamber 100 of FIG. 1. In another embodiment, the thermal process may be a dopant activation process performed following a plasma doping operation.

At 210, a second layer is deposited on the substrate by forming a plasma in the multi-functional chamber. The second layer may be any layer typically formed by a plasma deposition process, include a second silicon layer, a metal oxide layer, a doped silicon layer, and the like.

While the foregoing is directed to embodiments of the invention, other and further embodiments of the invention may be devised without departing from the basic scope thereof.

1. A chamber for processing semiconductor substrates, comprising:
a substrate support disposed in the chamber;
an in-situ plasma source facing the substrate support; and
a remote plasma source connected to the chamber through the in-situ plasma source.

2. The chamber of claim 1, wherein the in-situ plasma source is an inductive plasma source.

3. The chamber of claim 1, wherein the in-situ plasma source comprises a conductive coil disposed in a lid region of the chamber.

4. The chamber of claim 1, wherein the in-situ plasma source comprises a showerhead coupled to a source of electric power, and the remote plasma source is connected to an opening in a central region of the showerhead.

5. The chamber of claim 1, further comprising a heat source disposed in the chamber, wherein the heat source is spaced apart from the substrate support.

6. The chamber of claim 5, wherein the substrate support is disposed between the heat source and the in-situ plasma source.

7. A chamber for processing semiconductor substrates, comprising:
a substrate support disposed in the chamber;
a high ion density plasma source disposed in the chamber facing the substrate support; and
a low ion density plasma source connected to the chamber.

8. The chamber of claim 7, wherein the low ion density plasma source is a remote plasma source.

9. The chamber of claim 7, further comprising a plurality of radiant heat sources disposed in the chamber.

10. The chamber of claim 9, further comprising a window between the substrate support and the radiant heat sources.

11. The chamber of claim 9, wherein the high ion density plasma source is an inductively coupled plasma source or a capacitively coupled plasma source, and the low ion density plasma source is a remote plasma source.

12. A chamber for processing semiconductor substrates, comprising:
a substrate support;
a direct plasma source facing the substrate support; and
a radiant heat source spaced apart from the substrate support.

13. The chamber of claim 12, wherein the direct plasma source is an inductively coupled RF, microwave, or millimeter wave plasma source.

14. The chamber of claim 12, further comprising a remote plasma source.

15. The chamber of claim 14, wherein the direct plasma source is inductively coupled plasma source.

16. The chamber of claim 15, wherein the direct plasma source is an RF, microwave, or millimeter wave source.
